(19) United States
(12) Patent Application Publication
(10) Pub. No.: US 2007/0040502 A1
(43) Pub. Date: Feb. 22, 2007

(54) High CRI LED lamps utilizing single phosphor

(75) Inventors: Anant Achyut Setlur, Niskayuna, NY (US); Emil Vergilov Radkov, Euclid, OH (US)

Correspondence Address: FAY, SHARPE, FAGAN, MINNICH & MCKEE, LLP, 1100 SUPERIOR AVENUE, SEVENTH FLOOR, CLEVELAND, OH, 44114, US

(73) Assignee: GELcore LLC

(21) Appl. No.: 11/586,811

(22) Filed: Oct. 26, 2006

Related U.S. Application Data
(63) Continuation-in-part of application No. 10/827,738, filed on Apr. 20, 2004.

(51) Int. Cl. H05B 33/00; H01L 51/50; H01L 33/00

(52) U.S. Cl. 313/512; 252/301.4 F; 313/485; 257/98; 257/100

(57) ABSTRACT

Disclosed are phosphor compositions having the formulas [Ba_{1-x-y-w-2z}SrₓCa_{y}Ce_{z}(Li,Na)_{z}Eu₂]₂Si₅N₈, where 0<w<O.1, 0<z<0.1, 0<=x<1, 0<=y<1; [Ba_{1-x-y-w-2z}SrₓCa_{y}Ce_{z}(Li,Na)_{z}Eu_{w}]Si₇N₁₀, where 0<z<0.1, 0<=x<0.1, 0<=x<1, 0<=y<0.3; and [Ca_{1-2x-y-w}(Na,Li)_{x+w}CeₓEu_{y}]Al_{1-w}Si_{1+w}N₃, where 0<w<=0.3, 0<x<=0.1, 0<y<=0.1. When combined with radiation from a blue or UV light source, these phosphors can provide light sources with good color quality having high CRI over a large color temperature range.

### PRIORITY

This application is a Continuation-in-Part and claims priority from U.S. patent application Ser. No. 10/827,738, filed on Apr. 20, 2004.

### BACKGROUND

The present exemplary embodiments relate to novel phosphor compositions. They find particular application in conjunction with converting LED-generated ultraviolet (UV), violet or blue radiation into white light or other colored light for general illumination purposes. It should be appreciated, however, that the invention is also applicable to the conversion of radiation from UV and/or blue lasers as well as other UV sources to white light.

Light emitting diodes (LEDs) are semiconductor light emitters often used as a replacement for other light sources, such as incandescent lamps. They are particularly useful as display lights, warning lights and indicating lights or in other applications where colored light is desired. The color of light produced by an LED is dependent on the type of semiconductor material used in its manufacture.

Colored semiconductor light emitting devices, including light emitting diodes and lasers (both are generally referred to herein as LEDs), have been produced from Group III-V alloys such as gallium nitride (GaN). To form the LEDs, layers of the alloys are typically deposited epitaxially on a substrate, such as silicon carbide or sapphire, and may be doped with a variety of n and p type dopants to improve properties, such as light emission efficiency. With reference to the GaN-based LEDs, light is generally emitted in the UV and/or blue range of the electromagnetic spectrum. Until quite recently, LEDs have not been suitable for lighting uses where a bright white light is needed, due to the inherent color of the light produced by the LED.

Recently, techniques have been developed for converting the light emitted from LEDs to useful light for illumination purposes. In one technique, the LED is coated or covered with a phosphor layer. A phosphor is a luminescent material that absorbs radiation energy in a portion of the electromagnetic spectrum and emits energy in another portion of the electromagnetic spectrum. Phosphors of one important class are crystalline inorganic compounds of very high chemical purity and of controlled composition to which small quantities of other elements (called “activators”) have been added to convert them into efficient fluorescent materials. With the right combination of activators and host inorganic compounds, the color of the emission can be controlled. Most useful and well-known phosphors emit radiation in the visible portion of the electromagnetic spectrum in response to excitation by electromagnetic radiation outside the visible range.

By interposing a phosphor excited by the radiation generated by the LED, light of a different wavelength, e.g., in the visible range of the spectrum, may be generated. Colored LEDs are often used in toys, indicator lights and other devices. Manufacturers are continuously looking for new colored phosphors for use in such LEDs to produce custom colors and higher luminosity.

In addition to colored LEDs, a combination of LED generated light and phosphor generated light may be used to produce white light. The most popular white LEDs are based on blue emitting GaInN chips. The blue emitting chips are coated with a phosphor that converts some of the blue radiation to a complementary color, e.g. a yellow-green emission. The total of the light from the phosphor and the LED chip provides a color point with corresponding color coordinates (x and y) in the CIE 1931 chromaticity diagram and correlated color temperature (CCT), and its spectral distribution provides a color rendering capability, measured by the color rendering index (CRI).

The CRI is commonly defined as a mean value for 8 standard color samples (R₁₋₈), usually referred to as the General Color Rendering Index and abbreviated as Rₐ.

One known white light emitting device comprises a blue light-emitting LED having a peak emission wavelength in the blue range (from about 440 nm to about 480 nm) combined with a phosphor, such as cerium doped yttrium aluminum garnet Y₃Al₅O₁₂:Ce³⁺ (“YAG”). The phosphor absorbs a portion of the radiation emitted from the LED and converts the absorbed radiation to a yellow-green light. The remainder of the blue light emitted by the LED is transmitted through the phosphor and is mixed with the yellow light emitted by the phosphor. A viewer perceives the mixture of blue and yellow light as a white light.

The blue LED-YAG phosphor device described above typically produces a white light with a general color rendering index (Rₐ) of from about 70-82 with a tunable color temperature range of from about 4000K to 8000K. Typical general lighting applications require a higher CRI and lower CCT values than possible using the blue LED-YAG approach. The limitation in CRI and CCT values for blue LED-YAG light sources is due in part to the lack of red in the device emission spectra. In an effort to improve the CRI, recent commercially available LEDs using a blend of YAG phosphor and one or more additional phosphors, including a red phosphor such as CaS:Eu²⁺ to provide color temperatures below 4000K with a Rₐ around 90.

However, these new red materials have the disadvantage of absorbing radiation emitted by the YAG phosphor, resulting in an inevitable loss mechanism due to the reduced quantum efficiency. State of the art red enhanced devices have a typical conversion efficiency of only about 70% that of blue LED-YAG devices.

Thus, there is a continued demand for additional phosphor compositions that can be used as a single phosphor component or as part of a phosphor blend in the manufacture of both white and colored LEDs as well as in other applications. Such phosphor compositions will allow an even wider array of LEDs with desirable properties including the ability to produce light sources with both good color quality (CRI>80) and a large range of color temperatures, including the possibility of reduced CCT compared to prior lamps.

### BRIEF DESCRIPTION

In a first aspect, there is provided a single phosphor lighting device having a CRI>80, comprising a semiconductor phosphor comprising light source having a peak emission from about 250 to about 550 nm and a single phosphor composition including a host lattice doped with Ce³⁺ and Eu²⁺.

In a second aspect, there is provided a single phosphor lighting device having a CRI>80, comprising a semiconductor light source having a peak emission from about 250 to about 550 nm and a single phosphor composition selected from the group comprising: [Ba_{1-x-y-w-2z}SrₓCa_{y}Ce_{z}(Li,Na)_{z}Eu_{w}]₂Si₅N₈, where 0<w<0.1, 0<z<0.1, 0<=x<1, 0<=y<1; [Ba_{1-x-y-w-2z}SrₓCa_{y}Ce_{z}(Li,Na)_{z}Eu_{w}]Si₇N₁₀, where 0<z<0.1, 0<x<0.1, 0<=x<1, 0<=y<0.3; and [Ca_{1-2x-y-w}(Na,Li)_{x+w}CeₓEu_{y}]Al_{1-w}Si_{1+w}N₃, where 0<w<=0.3, 0<x<=0.1, 0<y<=0.1.

In a third aspect, there is provided a method for converting UV to blue exciting radiation to provide a white light including the step of directing exciting radiation from a UV to blue radiation source to a luminescence material comprising a single phosphor composition including a host lattice doped with Ce³⁺ and Eu²⁺, such that a combined emission of said radiation source and said phosphor composition comprises a white light having a CRI>80.

### BRIEF DESCRIPTION OF THE DRAWINGS

FIG. 1 is a schematic cross-sectional view of an illumination system in accordance with one embodiment of the present invention.

FIG. 2 is a schematic cross-sectional view of an illumination system in accordance with a second embodiment of the present invention.

FIG. 3 is a schematic cross-sectional view of an illumination system in accordance with a third embodiment of the present invention.

FIG. 4 is a cutaway side perspective view of an illumination system in accordance with a fourth embodiment of the present invention.

FIG. 5 is the emission spectra of a phosphor according to the present invention having varying amounts of Eu²⁺ dopant.

### DETAILED DESCRIPTION

Phosphors convert radiation (energy) to visible light. Different combinations of phosphors provide different colored light emissions. The colored light that originates from the phosphors provides a color temperature. Novel phosphor compositions are presented herein as well as their use in LED and other light sources.

A phosphor conversion material (phosphor material) converts generated UV or blue radiation to a different wavelength visible light. The color of the generated visible light is dependent on the particular components of the phosphor material. The phosphor material may include only a single phosphor composition or two or more phosphors of basic color, for example a particular mix with one or more of a yellow and red phosphor to emit a desired color (tint) of light. As used herein, the term “phosphor material” is intended to include both a single phosphor composition as well as a blend of two or more phosphor compositions.

It was determined that an LED lamp that produces a bright-white light would be useful to impart desirable qualities to LEDs as light sources. Therefore, in one embodiment of the invention, a luminescent phosphor conversion material coated LED chip is disclosed for providing white light. The phosphor material may be an individual phosphor composition that converts radiation at a specified wavelength, for example radiation from about 250 to 550 nm as emitted by a UV to visible LED, into a different wavelength visible light. The visible light provided by the phosphor material (and LED chip if emitting visible light) comprises a bright white light with high intensity and brightness.

With reference to FIG. 1, an exemplary LED based light emitting assembly or lamp 10 is shown in accordance with one preferred structure of the present invention. The light emitting assembly 10 comprises a semiconductor UV or visible radiation source, such as a light emitting diode (LED) chip 12 and leads 14 electrically attached to the LED chip. The leads 14 may comprise thin wires supported by a thicker lead frame(s) 16 or the leads may comprise self supported electrodes and the lead frame may be omitted. The leads 14 provide current to the LED chip 12 and thus cause the LED chip 12 to emit radiation.

The lamp may include any semiconductor visible or UV light source that is capable of producing white light when its emitted radiation is directed onto the phosphor. The preferred peak emission of the LED chip in the present invention will depend on the identity of the phosphors in the disclosed embodiments and may range from, e.g., 250-550 nm. In one preferred embodiment, however, the emission of the LED will be in the near UV to deep blue region and have a peak wavelength in the range from about 350 to about 500 nm. Typically then, the semiconductor light source comprises an LED doped with various impurities. Thus, the LED may comprise a semiconductor diode based on any suitable III-V, II-VI or IV-IV semiconductor layers and having a peak emission wavelength of about 250 to 550 nm.

Preferably, the LED may contain at least one semiconductor layer comprising GaN, ZnSe or SiC. For example, the LED may comprise a nitride compound semiconductor represented by the formula InⱼGaₖAlₗN (where 0≦j; 0≦k; 0≦l and j+k+l=1) having a peak emission wavelength greater than about 250 nm and less than about 550 nm. Such LED semiconductors are known in the art. The radiation source is described herein as an LED for convenience. However, as used herein, the term is meant to encompass all semiconductor radiation sources including, e.g., semiconductor laser diodes.

Although the general discussion of the exemplary structures of the invention discussed herein are directed toward inorganic LED based light sources, it should be understood that the LED chip may be replaced by an organic light emissive structure or other radiation source unless otherwise noted and that any reference to LED chip or semiconductor is merely representative of any appropriate radiation source.

The LED chip 12 may be encapsulated within a shell 18, which encloses the LED chip and an encapsulant material 20. The shell 18 may be, for example, glass or plastic. Preferably, the LED 12 is substantially centered in the encapsulant 20. The encapsulant 20 is preferably an epoxy, plastic, low temperature glass, polymer, thermoplastic, thermoset material, resin, silicone, or other type of LED encapsulating material as is known in the art. Optionally, the encapsulant 20 is a spin-on glass or some other high index of refraction material. Preferably, the encapsulant material 20 is an epoxy or a polymer material, such as silicone. Both the shell 18 and the encapsulant 20 are preferably transparent or substantially optically transmissive with respect to the wavelength of light produced by the LED chip 12 and a phosphor material 22 (described below). In an alternate embodiment, the lamp 10 may only comprise an encapsulant material without an outer shell 18. The LED chip 12 may be supported, for example, by the lead frame 16, by the self supporting electrodes, the bottom of the shell 18, or by a pedestal (not shown) mounted to the shell or to the lead frame.

The structure of the illumination system includes a phosphor material 22 radiationally coupled to the LED chip 12. Radiationally coupled means that the elements are associated with each other so radiation from one is transmitted to the other.

This phosphor material 22 is deposited on the LED 12 by any appropriate method. For example, a water based suspension of the phosphor(s) can be formed, and applied as a phosphor layer to the LED surface. In one such method, a silicone slurry in which the phosphor particles are randomly suspended is placed around the LED. This method is merely exemplary of possible positions of the phosphor material 22 and LED 12. Thus, the phosphor material 22 may be coated over or directly on the light emitting surface of the LED chip 12 by coating and drying the phosphor suspension over the LED chip 12. Both the shell 18 and the encapsulant 20 should be transparent to allow light 24 to be transmitted through those elements. Although not intended to be limiting, in one embodiment, the median particle size of the phosphor material may be from about 1 to about 10 microns.

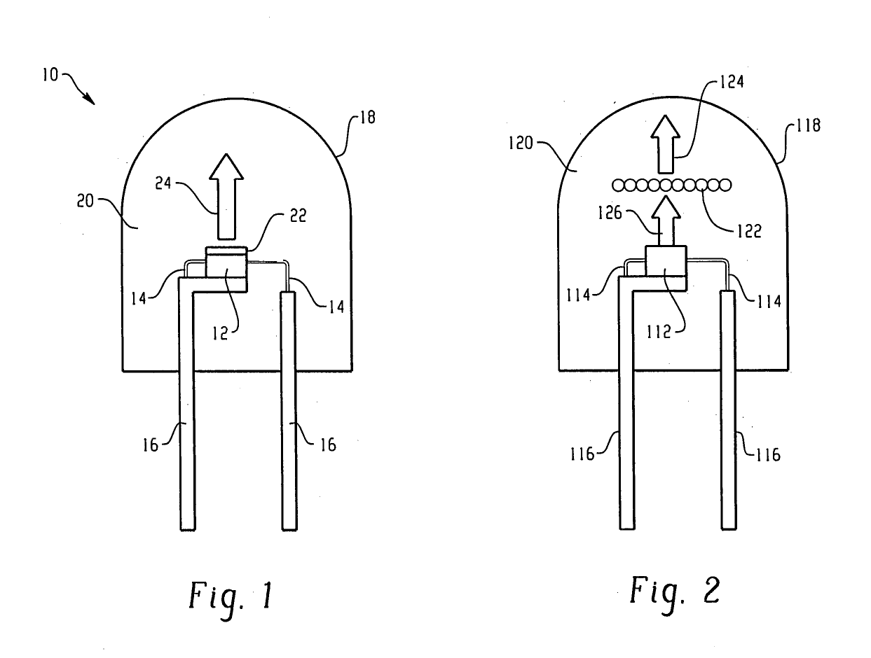

FIG. 2 illustrates a second preferred structure of the system according to the preferred aspect of the present invention. The structure of the embodiment of FIG. 2 is similar to that of FIG. 1, except that the phosphor material 122 is interspersed within the encapsulant material 120, instead of being formed directly on the LED chip 112. The phosphor material (in the form of a powder) may be interspersed within a single region of the encapsulant material 120 or, more preferably, throughout the entire volume of the encapsulant material. Radiation 126 emitted by the LED chip 112 mixes with the light emitted by the phosphor material 122, and the mixed light appears as white light 124. If the phosphor is to be interspersed within the encapsulant material 120, then a phosphor powder may be added to a polymer precursor, loaded around the LED chip 112, and then the polymer precursor may be cured to solidify the polymer material. Other known phosphor interspersion methods may also be used, such as transfer loading.

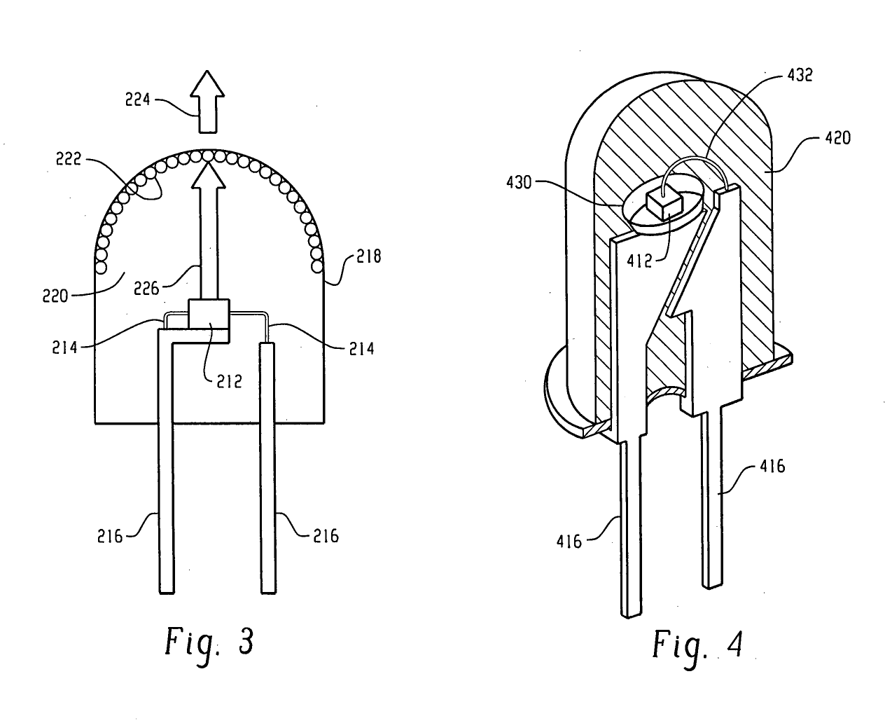

FIG. 3 illustrates a third preferred structure of the system according to the preferred aspects of the present invention. The structure of the embodiment shown in FIG. 3 is similar to that of FIG. 1, except that the phosphor material 222 is coated onto a surface of the shell 218, instead of being formed over the LED chip 212. The phosphor material is preferably coated on the inside surface of the shell 218, although the phosphor may be coated on the outside surface of the shell, if desired. The phosphor material 222 may be coated on the entire surface of the shell or only a top portion of the surface of the shell. The radiation 226 emitted by the LED chip 212 mixes with the light emitted by the phosphor material 222, and the mixed light appears as white light 224. Of course, the structures of FIGS. 1-3 may be combined and the phosphor may be located in any two or all three locations or in any other suitable location, such as separately from the shell or integrated into the LED.

In any of the above structures, the lamp 10 may also include a plurality of scattering particles (not shown), which are embedded in the encapsulant material. The scattering particles may comprise, for example, Al₂O₃ particles such as alumina powder or TiO₂ particles. The scattering particles effectively scatter the coherent light emitted from the LED chip, preferably with a negligible amount of absorption.

As shown in a fourth preferred structure in FIG. 4, the LED chip 412 may be mounted in a reflective cup 430. The cup 430 may be made from or coated with a reflective material, such as alumina, titania, or other dielectric powder known in the art. A preferred reflective material is Al₂O₃. The remainder of the structure of the embodiment of FIG. 4 is the same as that of any of the previous Figures, and includes two leads 416, a conducting wire 432 electrically connecting the LED chip 412 with the second lead, and an encapsulant material 420.

In one embodiment, the invention provides a phosphor composition for use in the above described LED light, wherein the phosphor lattice is doped with both Ce³⁺ and Eu²⁺ ions. Since energy transfer occurs between these two ions, one can control the composition of new phosphors for color, absorption and efficiency in LED packages.

The concept is based on Ce³⁺ acting as a “sensitizer”, absorbing the radiation emitted by the LED, which may range, e.g., from about 370-520 in one embodiment. This absorption is based upon proper host lattice selection such that there is a strong crystal field on the Ce³⁺ 5d orbitals and/or a high covalency of the Ce-ligand bond. After absorption, energy is transferred from the Ce³⁺ ions to Eu²⁺ ions, which then release the energy by emitting in the visible region. Since the absorption/emission transitions for Ce³⁺ and Eu²⁺ are parity allowed transitions, energy transfer should readily and efficiently occur, even at low concentration of either ion.

With proper composition/synthesis control, one can control the overall phosphor color by adjusting the Ce³⁺/Eu²⁺ emission intensity ratio. In addition, the overall concentration of Eu²⁺ in the host lattice can be reduced compared to conventional Eu²⁺ only doped phosphors (such as CaS:Eu²⁺) since Ce³⁺ will also absorb LED radiation. Because Eu²⁺ doped phosphors are known to absorb the radiation emitted by other phosphors present in the device, this has the additional benefit of increasing the device package efficiency when additional phosphors are present (such as YAG:Ce), since less of the light emitted by these phosphors will be absorbed due to the lower concentration of Eu²⁺. In one embodiment, the Ce³⁺ doping levels may range from about 0.01 to about 20 mol % replacement and the Eu²⁺ doping levels may range from about 0.01 to about 30 mol %. Charge compensation can occur via, e.g., K, Na, Li, Rb, or Cs ions.

In one embodiment, the phosphor material comprises a single phosphor composition, which may be used in the above described LED light, wherein the composition is selected from [Ba_{1-x-y-w-2z}SrₓCa_{y}Ce_{z}(Li,Na)_{z}Eu_{w}]₂Si₅N₈, where 0<w<0.1, 0<z<0.1, 0<=x<1, 0<=y<1; [Ba_{1-x-y-w-2z}SrₓCa_{y}Ce_{z}(Li,Na)_{z}Eu_{w}]Si₇N₁₀, where 0<z<0.1, 0<x<0.1, 0<=x<1, 0<=y<0.3; and [Ca_{1-2x-y-w}(Na,Li)_{x+w}CeₓEu_{y}]Al_{1-w}Si_{1+w}N_{3,} where 0<w<=0.3, 0<x<=0.1, 0<y<=0.1. For the first two phosphors, it is preferred if z>w and w<0.01. For the third phosphor, it is preferred if x>y and y<0.01.

It should be noted that various phosphors are described herein in which different elements enclosed in parentheses and separated by commas, such as Li and Na in the above [Ba_{1-x-y-w-2z}SrₓCa_{y}Ce_{z}(Li,Na)_{z}Eu_{w}]₂Si₅N₈ phosphor. As understood by those skilled in the art, this type of notation means that the phosphor can include any or all of those specified elements in the formulation in any ratio from 0 to 100%. That is, this type of notation, for the above phosphor for example, has the same meaning as [Ba_{1-x-y-w-2z}SrₓCa_{y}Ce_{z}(Li₁₋ₘNaₘ)_{z}Eu_{w}]₂Si₅N₈, wherein 0≦m≦1.

Exemplary phosphor compositions according to one or more of these embodiments are (Ca_{0.979}Ce_{0.01}Na_{0.01}Eu_{0.0001})₂Si₅N₈, and (Ca_{0.978}Ce_{0.01}Na_{0.01}Eu_{0.002})₂Si₅N₈.

These Ce³⁺ and Eu²⁺ doped phosphors can be used individually with UV to blue LED chips to generate white light for general illumination. These phosphors can also be used in blends with other phosphors to produce a white light emitting device with CCTs ranging from 2500 to 10,000 K and CRIs ranging from 80-99.

As stated, the inventive phosphors can be used alone with an LED chip to make white light sources. This white light may, for instance, may possess an x value in the range of about 0.30 to about 0.55, and a y value in the range of about 0.30 to about 0.55. As stated, however, the exact identity of the phosphor and LED chip will determine the ultimate color temperature and CRI of the lamp.

The above described phosphor composition may be produced using known solution or solid state reaction processes for the production of phosphors by combining, for example, elemental nitrides, oxides, carbonates and/or hydroxides as starting materials. Other starting materials may include nitrates, sulfates, acetates, citrates, or oxalates. Alternately, coprecipitates of the rare earth oxides could be used as the starting materials for the RE elements. In a typical process, the starting materials are combined via a dry or wet blending process and fired in air or under a reducing atmosphere or in ammonia at from, e.g., 1000 to 1600° C.

A fluxing agent may be added to the mixture before or during the step of mixing. This fluxing agent may be AlF₃, NH₄Cl or any other conventional fluxing agent. A quantity of a fluxing agent of less than about 20, preferably less than about 10, percent by weight of the total weight of the mixture is generally adequate for fluxing purposes.

The starting materials may be mixed together by any mechanical method including, but not limited to, stirring or blending in a high-speed blender or a ribbon blender. The starting materials may be combined and pulverized together in a bowl mill, a hammer mill, or a jet mill. The mixing may be carried out by wet milling especially when the mixture of the starting materials is to be made into a solution for subsequent precipitation. If the mixture is wet, it may be dried first before being fired under a reducing atmosphere at a temperature from about 900° C. to about 1700° C., preferably from about 1100° C. to about 1600° C., for a time sufficient to convert all of the mixture to the final composition.

The firing may be conducted in a batchwise or continuous process, preferably with a stirring or mixing action to promote good gas-solid contact. The firing time depends on the quantity of the mixture to be fired, the rate of gas conducted through the firing equipment, and the quality of the gas-solid contact in the firing equipment. Typically, a firing time up to about 10 hours is adequate but for phase formation it is desirable to refire couple of times at the desired temperatures after grinding. The reducing atmosphere typically comprises a reducing gas such as hydrogen, carbon monoxide, ammonia or a combination thereof, optionally diluted with an inert gas, such as nitrogen, helium, etc., or a combination thereof. A typical firing atmosphere is 2% H₂ in nitrogen. Alternatively, the crucible containing the mixture may be packed in a second closed crucible containing high-purity carbon particles and fired in air so that the carbon particles react with the oxygen present in air, thereby, generating carbon monoxide for providing a reducing atmosphere.

It may be desirable to add pigments or filters to the phosphor composition. When the LED is a UV emitting LED, the phosphor layer 22 may also comprise from 0 up to about 5% by weight (based on the total weight of the phosphors) of a pigment or other UV absorbent material capable of absorbing or reflecting UV radiation having a wavelength between 250 nm and 550 nm.

Suitable pigments or filters include any of those known in the art that are capable of absorbing radiation generated between 250 nm and 550 nm. Such pigments include, for example, nickel titanate or praseodymium zirconate. The pigment is used in an amount effective to filter 10% to 100% of the radiation generated in any of the 250 nm to 550 nm range.

### EXAMPLES

Several phosphor compositions according to the above embodiments were produced to investigate the effect of varying amounts of Ce and Eu dopant in the phosphors on emission wavelength and intensity. Three different exemplary compositions are presented. These compositions were: (Ca_{0.98}Ce_{0.01}Na_{0.01})₂Si₅N₈; (Ca_{0.979}Ce_{0.01}Na_{0.01}Eu_{0.001})₂Si₅N₈; and (Ca_{0.978}Ce_{0.01}Na_{0.01}Eu_{0.002})₂Si₅N₈.

The raw materials and amounts used to make each of these phosphors are listed below:

Sample A: (Ca_{0.98}Ce_{0.01}Na_{0.01})₂Si₅N₈

| | |
|---|---|
| Ca₃N₂: | 1.651 g |
| CeF₃: | 0.067 g |
| NaCl: | 0.040 g (100% excess) |
| Si₃N₄: | 3.985 g |

Sample B: (Ca_{0.979}Ce_{0.01}Na_{0.01}Eu_{0.001})₂Si₅N₈

| | |
|---|---|
| Ca₃N₂: | 1.648 g |
| CeF₃: | 0.067 g |
| EuF₃: | 0.007 g |
| NaCl: | 0.040 g (100% excess) |
| Si₃N₄: | 3.983 g |

Sample C: (Ca_{0.978}Ce_{0.01}Na_{0.01}Eu_{0.001})₂Si₅N₈

| | |
|---|---|
| Ca₃N₂: | 1.646 g |
| CeF₃: | 0.067 g |
| EuF₃: | 0.014 g |
| NaCl: | 0.040 g (100% excess) |
| Si₃N₄: | 3.981 g |

All powder precursors were blended under inert atmosphere conditions and placed into Mo crucibles. Samples were fired at 1500 C for 5 hrs at 2% H₂/N₂. After firing, sample were ground and milled in water for 30 minutes to achieve a median particle size <7 mm. The milled samples were then washed in hot water for one hour and then dried in air.

The color points of these phosphors under 405 nm excitation on the CIE color chart are shown below in table 1. The CCT of sample B is 2500 and the CRI is 81.

TABLE 1

| Sample | (x, y) under 405 nm excitation |
|---|---|
| A | (0.26, 0.38) |
| B | (0.46, 0.40) |
| C | (0.54, 0.45) |

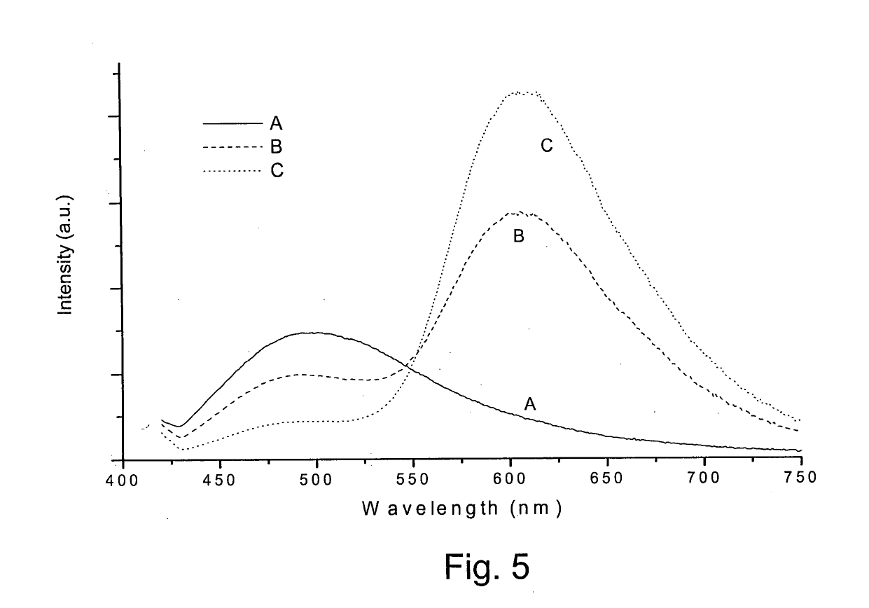

The simulated emission of these phosphors under 405 nm excitation are shown in FIG. 5. As can be seen, the inclusion of Eu as a codopant shifts the peak emission to a higher wavelength.

By use of the present invention, single phosphor lamps can be provided having CRI values greater than those achievable using YAG alone over a wide range of color temperatures. In addition, the use of the present phosphors in LED lamps can produce lamps with CRI values over 80, over a wide range of color temperatures of interest for general illumination (2500 K to 10,000 K). In some blends, the CRI values may approach the theoretical maximum of 100.

The phosphor composition described above may be used in additional applications besides LEDs. For example, the material may be used as a phosphor in a Hg fluorescent lamp or fluorescent lamps based upon alternate discharges, in a cathode ray tube, in a plasma display device or in a liquid crystal display (LCD). These are exemplary uses and not exhaustive.

The exemplary embodiment has been described with reference to the preferred embodiments. Obviously, modifications and alterations will occur to others upon reading and understanding the preceding detailed description. It is intended that the exemplary embodiment be construed as including all such modifications and alterations insofar as they come within the scope of the appended claims or the equivalents thereof.

What is claimed is:

1. A lighting apparatus for emitting white light comprising:
a light source emitting radiation with a peak at from about 250 nm to about 550 nm; and a phosphor material radiationally coupled to the light source, the phosphor material comprising a single phosphor composition including a host lattice doped with Ce³⁺ and Eu²⁺, wherein the light emitted by said apparatus has a general CRI (Ra) of at least 80.

2. The lighting apparatus of claim 1, wherein the light source is a semiconductor light emitting diode (LED) emitting radiation having a peak wavelength in the range of from about 350 to about 500 nm.

3. The lighting apparatus of claim 2, wherein the LED comprises a nitride compound semiconductor represented by the formula InᵢGaⱼAlₖN, where 0≦i; 0≦j, 0≦K, and i+j+k=1.

4. The lighting apparatus of claim 1, wherein the light source is an organic emissive structure.

5. The lighting apparatus of claim 1, wherein the phosphor composition is coated on the surface of the light source.

6. The lighting apparatus of claim 1, further comprising an encapsulant surrounding the light source and the phosphor composition.

7. The lighting apparatus of claim 1, wherein the phosphor composition is dispersed in the encapsulant.

8. The lighting apparatus of claim 1, further comprising a reflector cup.

9. The lighting apparatus of claim 1, wherein said single phosphor composition is the composition is selected from the group consisting of [Ba_{1-x-y-w-2z}SrₓCa_{y}Ce_{z}(Li,Na)_{z}Eu_{w}]₂Si₅N₈, where 0<w<0.1, 0<z<0.1, 0<=x<1, 0<=y<1; [Ba_{1-x-y-w-2z}SrₓCa_{y}Ce_{z}(Li,Na)_{z}Eu_{w}]Si₇N₁₀, where 0<z<0.1, 0<x<0.1, 0<=x<1, 0<=y<0.3; and [Ca_{1-2x-y-w}(Na,Li)_{x+w}CeₓEu_{y}]Al_{1-w}Si_{1+w}N₃, where 0<w<=0.3, 0<x<=0.1, 0<y<=0.1.

10. The lighting apparatus of claim 1, wherein said single phosphor composition comprises either (Ca_{0.979}Ce_{0.01}Na_{0.01}Eu_{0.001})₂Si₅N₈, or (Ca_{0.978}Ce_{0.01}Na_{0.01}Eu_{0.002})₂Si₅N₈.

11. A phosphor material comprising at least one of [Ba_{1-x-y-w-2z}SrₓCa_{y}Ce_{z}(Li,Na)_{z}Eu_{w}]₂Si₅N₈, where 0<w<0.1, 0<z<0.1, 0<=x<1, 0<=y<1; [Ba_{1-x-y-w-2z}SrₓCa_{y}Ce_{z}(Li,Na)_{z}Eu_{w}]Si₇N₁₀, where 0<z<0.1, 0<x<0.1, 0<=x<1, 0<=y<0.3; and [Ca_{1-2x-y-w}(Na,Li)_{x+w}CeₓEu_{y}]Al_{1-w}Si_{1+w}N₃, where 0<w<=0.3, 0<x<=0.1, 0<y<=0.1.

12. A lighting apparatus for emitting white light comprising:
a light source emitting radiation with a peak at from about 250 nm to about 550 nm; and a phosphor material radiationally coupled to the light source, the phosphor material comprising a single phosphor composition including a host lattice doped with Ce³⁺ and Eu²⁺, wherein said phosphor composition is selected from the group consisting of: [Ba_{1-x-y-w-2z}SrₓCa_{y}Ce_{z}(Li,Na)_{z}Eu_{w}]₂Si₅N₈, where 0<w<0.1, 0<z<0.1, 0<=x<1, 0<=y<1; [Ba_{1-x-y-w-2z}SrₓCa_{y}Ce_{z}(Li,Na)_{z}Eu_{w}]Si₇N₁₀, where 0<z<0.1, 0<x<0.1, 0<=x<1, 0<=y<0.3; and [Ca_{1-2x-y-w}(Na,Li)_{x+w}CeₓEu_{y}]Al_{1-w}Si₁₊₂N_{3,} where 0<w<=0.3, 0<x<=0.1, 0<y<=0.1; and wherein the light emitted by said apparatus has a general CRI (Ra) of at least 80.

13. A method for converting UV to blue exciting radiation to provide a white light including the step of directing exciting radiation from a UV to blue semiconductor radiation source onto a luminescence material comprising a single phosphor composition including a host lattice doped with Ce³⁺ and Eu²⁺, such that a combined emission of said radiation source and said phosphor composition comprises a white light having a CRI>80.

14. A method according to claim 13, wherein said phosphor composition is selected from the group consisting of: [Ba_{1-x-y-w-2z}SrₓCa_{y}Ce_{z}(Li,Na)_{z}Eu₂]₂Si₅N₈, where 0<w<0.1, 0<z<0.1, 0<=x<1, 0<=y<1; [Ba_{1-x-y-w-2z}SrₓCa_{y}Ce_{z}(Li,Na)_{z}Eu_{w}]Si₇N₁₀, where 0<z<0.1, 0<x<0.1, 0<=x<1, 0<=y<0.3; and [Ca_{1-2x-y-w}(Na,Li)_{x+w}CeₓEu_{y}]Al_{1-w}Si_{1+w}N₃, where 0<w<=0.3, 0<x<=0.1, 0<y<=0.1.

15. A method according to claim 14, wherein said phosphor composition comprises at least one of (Ca_{0.979}Ce_{0.01}Na_{0.01}Eu_{0.001})₂Si₅N₈ and (Ca_{0.978}Ce_{0.01}Na_{0.01}Eu_{0.002})₂Si₅N₈.
